(19) United States
(12) Patent Application Publication
(10) Pub. No.: US 2022/0180153 A1
(43) Pub. Date: Jun. 9, 2022

(54) METHOD AND DEVICE FOR GENERATING A COMPUTER-READABLE MODEL FOR A TECHNICAL SYSTEM

(71) Applicant: Siemens Aktiengesellschaft, München (DE)

(72) Inventors: Andrés Botero Halblaub, Kirchseeon (DE); Andreas Garhammer, Reut (DE); Jan Fischer, München (DE); Jan Christoph Wehrstedt, München (DE); Yayun Zhou, München (DE); Siyuan Liu, München (DE)

(21) Appl. No.: 17/601,278

(22) PCT Filed: Mar. 25, 2020
(86) PCT No.: PCT/EP2020/058248

§ 371 Date: Oct. 4, 2021

(30) Foreign Application Priority Data
Apr. 23, 2019 (EP) 19170588.8

(51) Int. Cl. G06N 3/04; G06N 3/08

(52) U.S. Cl. CPC G06N 3/0454; G06N 3/08

(57) ABSTRACT

A computer-implemented method for generating a computer-readable model for a technical system on the basis of text-based specification data for the technical system, the text-based specification data specifying at least one system condition is provided. A plurality of model components for the computer-aided modelling of the technical system are provided, each model component being assigned a model component identifier. By means of generative adversarial networks, model components are selected, using their model component identifiers, from the plurality of model components on the basis of the text-based specification data, and a computer-readable model for the technical system is generated from the selected model components in such a way that model data of the computer-readable model satisfy at least one system condition specified in the text-based specification data.

### CROSS-REFERENCE TO RELATED APPLICATIONS

This application claims priority to PCT Application No. PCT/EP2020/058248, having a filing date of Mar. 25, 2020, which is based off of EP Application No. 19170588.8, having a filing date of Apr. 23, 2019, the entire contents both of which are hereby incorporated by reference.

### FIELD OF TECHNOLOGY

The following relates to a computer-implemented method and to a device for generating a computer-readable model for a technical system by means of an artificial neural network, in particular by means of Generative Adversarial Neural Networks. Furthermore, the following relates to a computer program product for carrying out the steps of an inventive method.

### BACKGROUND

Computer-assisted simulations can be used as a digital planning instrument of technical systems, for example plant or factories. Draft plans, for example, can be validated by means of simulations. Furthermore, computer simulations can be used during the operating phase of a plant in order, for example, to implement operation-smoothing assistance systems. Simulation tools are known for both types of simulation, with which tools it is possible for a simulation expert to manually create simulation models from existing simulation component libraries. As a rule, the creation of a simulation model on the basis of an available factory plan and available factory data requires a high degree of expert knowledge by simulation experts since they firstly have to determine and/or create suitable simulation components in order to map the real factory components. The creation of a simulation model can be time-consuming, error-prone and/or of varying quality, therefore.

Further so-called Generative Adversarial Networks, GAN for short, are known, which form part of the algorithms for unsupervised learning. Generative Adversarial Networks comprise two artificial neural networks, which are trained in such a way that one of the neural networks (the generator) creates candidates and the second neural network (the discriminator) assesses these candidates. Generative Adversarial Networks can be used, for example, for the image generation of photo-realistic images, videos or sequences.

### SUMMARY

An aspect relates to facilitate the creation of a computer-assisted model for a technical system, such as for a factory.

According to a first aspect, embodiments of the invention relate to a computer-implemented method for generating a computer-readable model for a technical system, comprising the following method steps:
acquiring text-based specification data for the technical system, wherein the text-based specification data specifies at least one system condition,
providing a large number of model components for computer-assisted modeling of the technical system, wherein one model component identifier is assigned to a respective model component,
providing a first neural network, which is trained by means of a second neural network to select, on the basis of text-based specification data for a technical system, model components, using the model component identifiers thereof, from a large number of model components and to generate from the selected model components a computer-readable model for the technical system in such a way that model data of the computer-readable model satisfies at least one system condition specified in the text-based specification data,
generating a computer-readable model for the technical system from the provided large number of model components as function of the acquired text-based specification data by means of the first neural network.

Unless specified otherwise in the description below, the terms “to carry out”, “to calculate”, “to provide”, “computer-assisted”, “to compute”, “to establish”, “to generate”, “to configure”, “to reconstruct”, “to extract” and the like refer to actions and/or processes and/or method steps, which are carried out by a computer and which modify and/or generate data and/or transfer the data into other data, it being possible for the data to be represented or be present in particular as physical variables, for example as electrical pulses. In particular, the expression “computer” should be interpreted as broadly as possible in order, in particular, to cover all electronic devices with data processing properties. Computers can thus be, for example, personal computers, servers, handheld computer systems, pocket PC devices, mobile phones and other communication devices, which can process data in a computer-assisted manner, processors and other electronic devices for data processing.

“Computer-assisted” or “computer-implemented” in connection with embodiments of the invention can be taken to mean, for example, an implementation of the method in which, in particular, a processor carries out at least one method step of the method. “Computer-readable” in connection with embodiments of the invention can be taken to mean, for example, a data set, which is constructed such that it can be read and/or interpreted by a computer. Furthermore, in particular a “computer-readable model “can comprise data, which can be read and processed by a computer. A computer-readable model can be, for example, a formal model or a computer-assisted simulation model.

Embodiments of the invention allows the creation of a computer-readable model for a technical system, which is adapted in such a way as to map and/or simulate the real technical system in a computer-assisted manner. A computer-assisted simulation or computer simulation serves, for example, to map and to analyze physical processes of the technical system.

A technical system can be, for example, a plant or a factory or a machine, such as a generator or a motor, or a machine tool, etc. A technical system comprises a large number of components. Components of the real technical system can be hardware and/or software components. Model components are corresponding maps of the real components. Model components can, in particular, be referred to as simulation components, which are configured in such a way that physical and/or functional processes and/or properties of the real component can be mapped in a computer-assisted manner thereby.

It is an advantage of embodiments of the present invention to automatically generate from a large number of model components, for example from a model component library, by means of a first trained artificial neural network, in particular a generative neural network, a computer-readable model for a technical system, which satisfies the input, text-based specification data. A model is thus generated for the technical system using a read, text-based specification of the technical system. A model with a topology, which corresponds to the topology of the corresponding real technical system, is consequently generated from the model components.

In addition, the method enables a reduction in the manual effort when creating a computer-readable model for a technical system since the model generation and model parameterization can be carried out automatically. This enables, in particular, a constant quality of the models. This data-based approach is, moreover, more robust and flexible than, for example, a rule-based approach in which models are generated using established rules.

The model components are selected using specific model identifiers and merged to form the computer-readable model. The generated, computer-readable model can be used, for example, for simulation and/or control and/or analysis of the technical system. In particular, the inventive method can be used to plan a technical system, in other words to firstly create a computer-readable model before the real technical system is constructed.

The model is generated on the basis of the acquired text-based specification data. Text-based specification data can be in the form, for example, of a textual requirement, which a technical system is to satisfy, such as a production target of a plant. Text-based specification data can comprise, for example, only boundary conditions and/or basic requirements of the technical system. These can be aligned subsequently with the model data of the generated model.

In an advantageous embodiment of the computer-implemented method, parameter values for parameters of the technical system and/or of components of the technical system are extracted using the text-based specification data for the technical system, and the generated computer-readable model is parameterized as a function of the extracted parameter values and by means of the first neural network.

The text-based specification data can comprise, for example, parameter values, which can be taken into account on generation of the computer-readable model. For this, information can be obtained, for example by means of a method for processing text data and/or natural speech from the text-based specification data, from which information it is possible to derive parameter values.

In an advantageous embodiment of the computer-implemented method, the first neural network can be trained by means of a second neural network and using training data,
wherein the training data can comprise at least text-based specification data of a technical system and/or model data of at least one computer-readable model of a technical system,
wherein training of the first neural network by means of the second neural network comprises that by means of the first neural network on the basis of text-based specification data for a technical system, model components are selected, using the model component identifiers thereof, from a large number of model components, a computer-readable model is generated for the technical system from the selected model components and by means of the second neural network a check is made using the training data as to whether the model data of the computer-assisted model generated by the first neural network satisfies the system condition specified in the text-based specification data.

The first neural network can also be referred to as the generator network. The second neural network can also be referred to as the discriminator network. Together they describe a Generative Adversarial Network. Both neural networks are trained jointly in particular. Training data comprises, for example, data relating to a large number of technical systems, wherein model data of computer-readable models as well as assigned text-based specification data are provided for each technical system. The generator network is trained by means of the discriminator network for the generation of a computer-readable model on the basis of text-based specification data for a technical system. The model is generated from a large number of model components and using the model component identifiers thereof. Model components are selected whose model component identifiers can be assigned to the text-based specification data. The generated, computer-readable model is checked by the second neural network using further (training) model data, which is assigned to the text-based specification data, as to whether the generated model satisfies the system condition specified in the text-based specification data. The trained generator network is then provided, for example stored, for generating a computer-readable model for a technical system.

In an advantageous embodiment of the computer-implemented method, a provided computer-assisted model can be validated for the technical system by means of the second neural network.

After the training of the Generative Adversarial Network the discriminator network can be used in particular, moreover, to validate a provided, computer-readable model. For this, the model data of the computer-readable model is checked by the trained second neural network and a test result output. It is possible to thus check, in particular, whether the topology of the computer-readable model and/or an output of a simulation on the basis of the computer-readable model is appropriate compared to the specified system conditions.

In an advantageous embodiment of the computer-implemented method, specification data of the technical system can be acquired by means of a speech input unit, be converted by means of an evaluation unit into text-based specification data and the text-based specification data can be provided.

For example, specification data can be verbally communicated by a user, be acquired by means of a speech input unit and be converted for further use into text-based specification data.

In an advantageous embodiment of the computer-implemented method, the computer-readable model can be generated as a computer-assisted simulation model in order to simulate the technical system.

The creation of a computer-assisted simulation model from the computer-readable model can be carried out by means of a simulation tool in a simulation unit, which comprises at least one processor. The input of the simulation unit is the output of the generative neural network. The computer-assisted simulation model can be created from provided simulation components. Simulation components are, for example, computer-assisted maps of the real components, which are configured in such a way that physical and/or functional processes and/or properties of the real component can be simulated in a computer-assisted manner thereby. A computer-assisted simulation model is, in particular, an executable model with which, for example, a course over time of a process of a technical system can be simulated in a computer-assisted manner.

In an advantageous embodiment of the computer-implemented method, the technical system and/or a process or a functionality of the technical system can be simulated by means of the computer-assisted simulation model in a computer-assisted manner and/or the computer-assisted simulation model can be output in order to control the technical system.

After the generation and parameterization of the computer-assisted simulation model, the simulation model can be provided and implemented in a simulation environment in a computer-assisted manner. In particular, the corresponding simulation data can then be output in order to control the real technical system. For example, a validation of a process and/or a functionality and/or a specification of the technical system can be carried out by means of the computer-assisted simulation.

The processor can be, in particular, a Central Processing Unit (CPU), a microprocessor or a microcontroller, for example an application-specific integrated circuit or a digital signal processor, possibly in combination with a storage unit for storing program commands, etc. A processor can also be, for example, an IC (Integrated Circuit) or a Graphics Processing Unit (GPU)/Tensor Processing Unit (TPU) or a Field Programmable Gate Array (FGPA). The processor can have one or more calculation core(s) (multi-core). A processor can also be taken to mean a virtualized processor or a soft CPU. It can also be, for example, a programmable processor, which is equipped with configuration steps for carrying out said inventive method or is configured with configuration steps in such a way that the programmable processor implements the inventive features of the method or other aspects and sub-aspects of embodiments of the invention.

The device can be coupled, for example, to a simulation unit or a simulation tool, so a computer-assisted simulation model can be generated and/or implemented in order to simulate the technical system.

Furthermore, embodiments of the invention relate to a computer program product (non-transitory computer readable storage medium having instructions, which when executed by a processor, perform actions) which can be loaded directly into a programmable computer, comprising program code segments, which are capable of carrying out an inventive, computer implemented method.

A computer program product, such as a computer program means or computer program, can be provided or supplied, for example as a storage medium or data carrier, such as a storage card, USB stick, CD-ROM, DVD or also in the form of a downloadable file from a server in a network.

### BRIEF DESCRIPTION

Some of the embodiments will be described in detail, with reference to the following figures, wherein like designations denote like members, wherein:

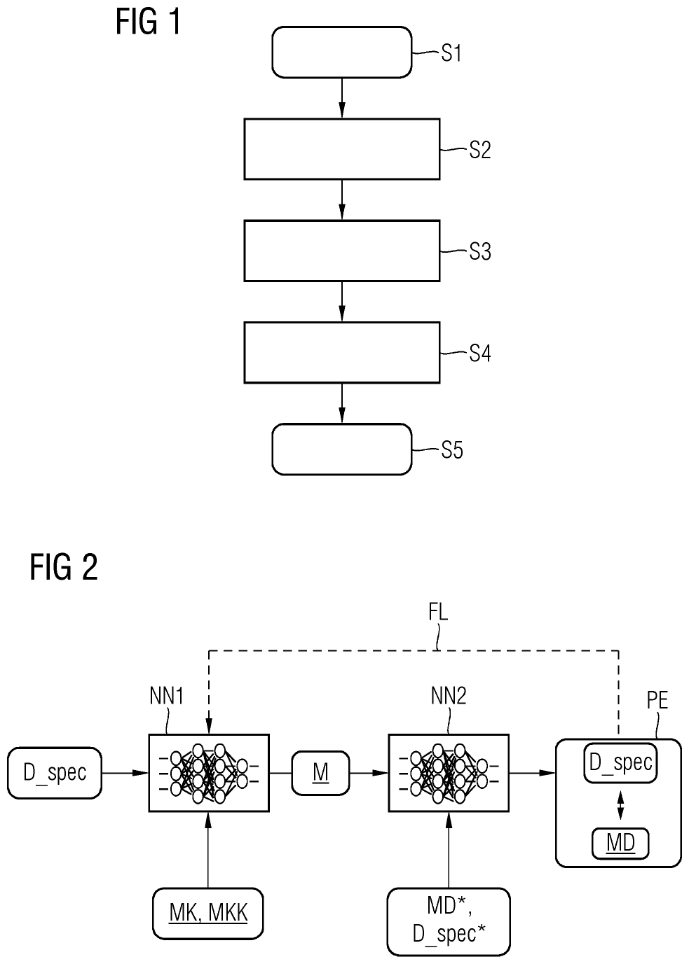

FIG. 1 shows a flowchart of an exemplary embodiment of an inventive method;

FIG. 2 shows a schematic representation of a further exemplary embodiment of an inventive method;

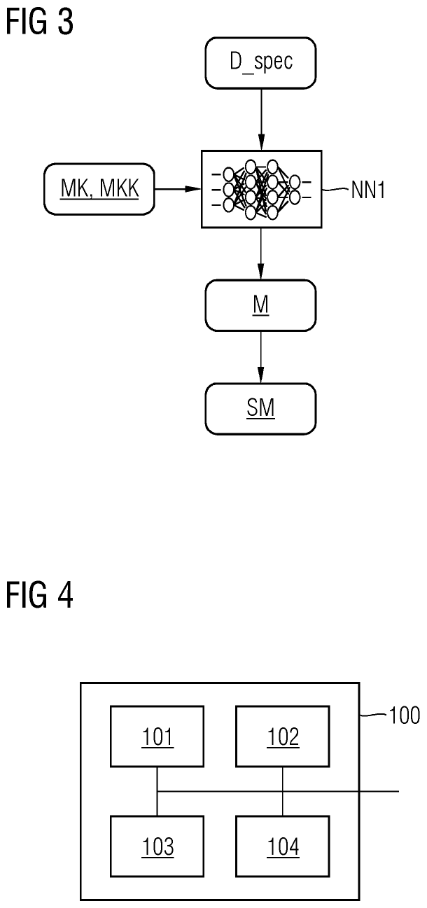

FIG. 3 shows a schematic representation of a further exemplary embodiment of an inventive method; and

FIG. 4 shows a schematic representation of an inventive device in a block diagram.

Mutually corresponding parts are provided with identical reference numerals in all figures.

### DETAILED DESCRIPTION

In particular, the following exemplary embodiments show only exemplary implementation options as to how, in particular, such implementations of the inventive disclosure could look since it is impossible and also not expedient or necessary to cite all of these implementation options for an understanding of embodiments of the invention.

FIG. 1 shows a flowchart of an inventive method for generating a computer-readable model for a technical system, such as a factory. The method can be used, for example, to plan a plant, which does not yet exist, on the computer.

In step S1, a text-based specification is provided for the plant to be modeled and is acquired as text-based specification data. This can include, for example, requirements, boundary conditions, construction conditions, operating conditions, a production target or the like for the factory. The text-based specification data can be provided, for example, by a user, in other words formulated and/or input for example and can be read for the further steps. Alternatively, the text-based specification data can be extracted and/or read from a file. A computer-readable model shall accordingly be created by means of the computer-implemented method, which model satisfies the system conditions specified for the factory in the text-based specification data. For example, a computer-readable model of a plant shall be generated, which satisfies a predefined production target for the plant. In other words, a plant comprising components shall be planned by means of the inventive method and a model comprising corresponding model components shall be generated for this, so the modeled plant satisfies the specified production target.

A computer-readable model can be, for example, a formalized engineering model, which is to be output as computer-readable text data, for example stored in an XML file. Alternatively, a computer-readable model can also be a computer simulation model, which can be read and run by a computer. In addition, a computer-readable model can be output as an abstract plant architecture, for example as a SysML or an AutomationML file.

In step S2, a large number of model components is provided for this purpose. For example, a library or database with model components is actuated for computer-assisted modeling of technical systems. Model components are each assigned to real components, such as software and/or hardware, of a real technical system, so a real component can be mapped or modeled and/or simulated by means of a model component.

A model component can be assigned to a real component, for example, in advance by means of a trained machine learning method, with the machine learning method being trained to assign one model component respectively, which maps the functionality and/or physics of the real component, to real components of a technical system.

A respective model component is identified by a model component identifier. A model component identifier can be in the form of identification data, which can comprise, for example, a designation, a marker, a name, a label, an identification number, description, brief description or the like. Model component identifiers are uniquely assigned to one model component. The respective model components and/or their function can be described and/or identified using identification data. Suitable model components can thus be selected, for example on the basis of the text-based specification data, using the model component identifiers thereof.

In step S3, a trained generative neural network is provided. The trained generative neural network is provided, for example, as a data structure, for example stored on a storage unit and read from there The generative neural network is firstly trained by means of a discriminator network, as is shown, for example, in FIG. 2. The generative neural network is trained in such a way that, on the basis of read, text-based specification data for a technical system, it selects particular model components from a model component database using respective model component identifiers and generates a computer-readable model from the selected model components. The generated, computer-readable model is created in such a way that the model data satisfies at least one system condition specified in read, text-based specification data. The model data of a generated model is compared, for example, with the specification data.

Alternatively, a system simulation can also be carried out by means of the generated model in order to test whether the model satisfies the specified system conditions. For example, the production of a product by means of the generated model can be simulated in order to test whether a production target of a plant is satisfied.

In step S4, the acquired text-based specification data is transferred and read into the trained generative neural network. The generative neural network generates a computer-readable model comprising model components of a model component database on the basis of the read text-based specification data.

In step S5, the generated, computer-readable model is output. For example, the generated, computer-readable model is output as a data structure. The computer-readable model can be used, for example, for planning, construction, for computer-assisted simulation and/or for controlling the factory. A factory, for example, can thus be planned and/or constructed and/or controlled by means of the output computer-readable model.

FIG. 2 shows an exemplary embodiment of an inventive method for training a Generative Adversarial Network, which is suitable for generating a computer-readable model for a technical system. In particular the training steps of the training of the first neural network NN1 and second neural network NN2 are shown.

Training a neural network should in general be taken to mean an optimization of a map of input parameters onto one or more target parameter(s). This map is optimized according to predefined, learned and/or to-be-learned criteria during a training phase. A training structure can comprise, for example, a connective structure of neurons of a neural network and/or weights of connections between the neurons, which are formed by the training such that the predefined criteria are optimally satisfied.

The first neural network NN1 generates a computer-readable model M on the basis of text-based specification data D_spec for a technical system. For this, the text-based specification data D_spec is read into the first neural network NN1. In addition, the first neural network NN1 is provided with a large number of model components MK, to which model component identifiers are assigned in each case. For example, the first neural network NN1 is coupled to a database or library in which model components MK are stored. From this the first neural network NN1 selects particular model components MK for the computer-readable model M on the basis of the read, text-based specification data D_spec and using the model component identifiers MKK.

For example, the specification data D_spec comprises the requirement “Plant for production of product X in time Y”, where “X” and “Y” have a particular value. Suitable model components can be selected, such as model components for machine tools, conveyor belts, etc., using this specification data D_spec. A computer-readable model is generated from the selected model components MK.

The generated computer-readable model M is output to the second neural network NN2 and read there. The second neural network NN2 checks the computer-readable model M using training data. For example, a check is made as to whether the generated computer-readable model M is appropriate. For this, the second neural network NN2 is provided with model data MD* and associated text-based specification data D_spec* from a large number of technical systems as the training data. In other words, the training data comprises at least one pair of mutually assigned model data MD* and text-based specification data D_spec*. The text-based specification data D_spec* of the training data is identical or similar to the originally read text-based specification data D_spec. For example, the training data MD*, D_spec* is from other technical systems and/or similar technical systems to the technical system to be modeled, which have identical or similar system conditions.

Using the training data MD*, D_spec* the second neural network NN2 can check whether the computer-readable model M generated by the first neural network NN1 satisfies the system condition specified in the text-based specification data D_spec. For this, the model data MD of the computer-readable model M is compared with the training data MD*, D_spec*. For example, a check can be made as to whether the model data MD follows a statistical distribution of the training model data MD*.

Renewed generation of a computer-readable model M can be initiated, FL, as a function of the check result PE if, for example, the model data MD does not satisfy the specified system condition D_spec. Training takes place until a computer-readable model is generated, which is checked by the second neural network NN2 for appropriateness or suitability, in other words the model data thereof satisfies the specified system condition at least within a predefined tolerance range. After training, the first and the second neural networks NN1, NN2 can be output and provided, for example, as a data structure.

For example, a predefined computer-readable model of a technical system can be validated by means of the trained second neural network NN2, in other words a check can be made as to whether the model is configured in such a way that it satisfies a system condition.

FIG. 3 shows a further exemplary embodiment of the inventive method. A trained first neural network NN1 is shown, which is configured as a generative neural network. Training of the first neural network NN1 can be carried out, for example, as shown using FIG. 2. The first neural network NN1 is coupled, for example, to a model component database, which provides model components MK each with associated model component identifiers MKK.

Text-based specification data D_spec for a technical system is provided and transferred to the first neural network NN1. The text-based specification data D_spec can be based, for example, on verbal specification data, which is acquired via a speech input unit and is output as text-based specification data D_spec.

Starting from the text-based specification data D_spec the neural network NN1 generates a computer-readable model M from a large number of model components MK. Model components MK are selected using their model component identifiers MKK as a function of the text-based specification data D_spec and are merged to form a computer-readable model M. Furthermore, parameter values for parameters of the technical system can be extracted using the text-based specification data D_spec, and the generated computer-readable model M can be parameterized as a function of the extracted parameter values and by means of the first neural network, in other words parameters of the model M are set. Parameters can be, for example, physical variables, which describe the model components.

The computer-readable model M can then be output, for example for technical system planning. Furthermore, a computer-assisted simulation model SM can be generated by means of a simulation tool on the basis of the computer-readable model M if, for example, the computer-readable model M is generated only as a formalized engineering model and is to be implemented as an executable simulation model.

A simulation tool can have an Application Programming Interface (API for short). The simulation model can be generated by the API of the simulation tool. The simulation tool or the internal functions of the tool can be accessed by way of the interface.

The technical system and/or a process or a functionality of the technical system can be simulated by means of the computer-assisted simulation model. The computer-assisted simulation model SM can be output in order to control the technical system.

FIG. 4 shows in a schematic representation an inventive device 100 for generating a computer-readable model for a technical system, for example for technical system planning. The device 100 comprises at least one processor 101, which is adapted to carry out the steps of an inventive method, as is shown, for example, using one of FIGS. 1 to 3. Furthermore, the device 100 comprises at least one storage unit 102 or is coupled to a storage unit or database. A large number of model components can be stored and provided on the storage unit 102. In addition, the storage unit 102 can store the trained first and/second neural network and provide them for use as a data structure in each case. For example, the Generative Adversarial Networks can be trained in a training unit 103 by means of training data and be transferred to the storage unit 102 or to the processor 101. The device 100 can also comprise a simulation unit 104 or be coupled thereto, with the simulation unit having, for example, a simulation tool in the form of software and being adapted in such a way as to create a simulation model that is executable on a computer from simulation components, and to output it. Furthermore, the simulation unit can also be adapted in such a way as to implement the simulation model. The individual units of the device 100 can be configured both as software and/or hardware and are advantageously coupled to each other.

Although the present invention has been disclosed in the form of preferred embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1. A computer-implemented method for generating a computer-readable model for a factory, comprising the method steps:
acquiring text-based specification data for the factory, wherein the text-based specification data specifies at least one system condition for the factory,
providing a large number of model components for computer-assisted modeling of the factory, wherein one model component identifier is assigned to a respective model component,
providing a first neural network, which is trained by means of a second neural network to select, on the basis of text-based specification data for a factory, model components, using the model component identifiers thereof, from a large number of model components and to generate from the selected model components a computer-readable model for the factory in such a way that model data of the computer-readable model satisfies at least one system condition specified in the text-based specification data,
generating a computer-readable model for the factory from the provided large number of model components as function of the acquired text-based specification data by means of the first neural network, wherein the computer-readable model is generated as a computer-assisted simulation model in order to simulate the factory,
and
outputting the generated computer-readable model, wherein a process or a functionality of the factory is simulated in a computer-assisted manner by means of the computer-assisted simulation model.

2. The computer-implemented method as claimed in claim 1, wherein, using the text-based specification data for the factory, parameter values for parameters of the factory are extracted and the generated computer-readable model is parameterized as a function of the extracted parameter values and by means of the first neural network.

3. The computer-implemented method as claimed in claim 1, wherein the first neural network is trained by means of a second neural network and using training data,
wherein the training data comprises at least text-based specification data of a factory and/or model data of at least one computer-readable model of a factory,
wherein training of the first neural network by means of the second neural network comprises that by means of the first neural network on the basis of text-based specification data for a factory, model components are selected, using the model component identifiers thereof, from a large number of model components, a computer-readable model for the factory is generated from the selected model components and by means of the second neural network a check is made using the training data as to whether the model data of the computer-assisted model generated by the first neural network satisfies the system condition specified in the text-based specification data.

4. The computer-implemented method as claimed in claim 1, wherein a provided computer-assisted model is validated for the factory by means of the second neural network.

5. The computer-implemented method as claimed in claim 1, wherein specification data of the factory is acquired by means of a speech input unit, is converted into text-based specification data by means of an evaluation unit and the text-based specification data is provided.

6. The computer-implemented method as claimed in claim 1, wherein the computer assisted simulation model is output in order to control the factory.

7. A device for generating a computer-readable model for a factory, wherein the device has at least one processor for carrying out the steps of the method as claimed in claim 1.

8. A computer program product, comprising a computer readable hardware storage device having computer readable program code stored therein, said program code executable by a processor of a computer system to implement a method adapted for carrying out the computer-assisted method as claimed in claim 1.

9. A computer-readable storage medium with the computer program product as claimed in claim 8.
